(19) United States
(12) Patent Application Publication
(10) Pub. No.: US 2025/0391694 A1
(43) Pub. Date: Dec. 25, 2025

(54) SUBSTRATE SUPPORT

(71) Applicant: Applied Materials, Inc., Santa Clara, CA (US)

(72) Inventors: Ajith KARONNAN RAMAPURATH, Bangalore (IN); Jian LI, Fremont, CA (US); Mayur Govind KULKARNI, Bangalore (IN); Jennifer Y. SUN, Mountain View, CA (US); Ganesh BALASUBRAMANIAN, Fremont, CA (US); Katherine WOO, Santa Clara, CA (US)

(21) Appl. No.: 18/750,046

(22) Filed: Jun. 21, 2024

(51) Int. Cl. H01L 21/683; H01J 37/32

(52) U.S. Cl. CPC H01L 21/6833; H01J 37/32568; H01J 37/32715

(57) ABSTRACT

A processing system for processing a substrate is provided. The processing system includes a process chamber that includes: a chamber body disposed around an interior volume; a substrate support assembly positioned in the interior volume, the substrate support assembly including a substrate support body and a first electrode disposed in the substrate support body. The substrate support body includes an inner portion and a ledge disposed around the inner portion. The ledge is positioned above the inner portion. The processing system further includes a controller configured to perform a process on a substrate that is positioned on the substrate support body in the interior volume of the process chamber; and apply a first counter voltage to the first electrode in the substrate support body based on a substrate voltage of the substrate during the process performed on the substrate in the interior volume of the process chamber.

### BACKGROUND

### Field

Embodiments of the present disclosure generally relate to improved substrate supports and related processing systems to be used for processing substrates, such as semiconductor substrates. More particularly, the improved substrate supports can be used in processing systems to limit or prevent damage to the back side of the substrate when the substrate is supported by the substrate support.

### Description of the Related Art

Substrates are placed on substrate supports during a variety of processes, such as semiconductor processes. The substrates can be susceptible to damage (e.g., mechanical damage) during handling and processing of the substrates. One area that is often damaged is the back side of the substrate. For example, substrates are often supported during processing by positioning the back side of the substrate or a portion of the back side of the substrate on a substrate support. The mechanical contact between the back side of the substrate and the supporting surface(s) of the substrate support can result in damage to the back side of the substrate. This damage can diminish the performance of the device that is ultimately manufactured from the substrate or undesirably alter subsequent processes performed on the substrate, such as causing non-uniformities during subsequent deposition or etching processes.

Thus, there is an ongoing need to limit and/or prevent damage to the back side of the substrates (e.g., semiconductor substrates) during processing and handling of the substrates.

### SUMMARY

In one embodiment, a processing system for processing a substrate is provided. The processing system includes a process chamber comprising: a chamber body disposed around an interior volume; a substrate support assembly positioned in the interior volume, the substrate support assembly comprising a substrate support body and a first electrode disposed in the substrate support body, wherein the substrate support body includes an inner portion and a ledge disposed around the inner portion, the ledge positioned above the inner portion. The processing system further includes a controller configured to perform a process on a substrate that is positioned on the substrate support body in the interior volume of the process chamber; and apply a first counter voltage to the first electrode in the substrate support body based on a substrate voltage of the substrate during the process performed on the substrate in the interior volume of the process chamber.

In another embodiment, a method of processing a substrate is provided comprising: positioning a substrate on a substrate support body of a substrate support assembly in an interior volume of a process chamber, wherein the substrate support assembly includes an electrode disposed in the substrate support body; providing one or more gases to the interior volume of the process chamber through a showerhead positioned over the substrate support body; applying radio frequency energy to the showerhead to generate a plasma in the interior volume of the process chamber, performing a process on the substrate positioned on the substrate support body with the generated plasma; determining a magnitude of a substrate voltage developed on the substrate during the process performed on the substrate; and applying a counter voltage to the electrode in the substrate support body based on the substrate voltage of the substrate during the process performed on the substrate, wherein a magnitude of the counter voltage applied to the electrode is based on the magnitude of the substrate voltage.

In another embodiment, a processing system for processing a substrate is provided. The processing system includes a process chamber comprising: a chamber body disposed around an interior volume; a substrate support assembly positioned in the interior volume, the substrate support assembly comprising a substrate support body and an electrode disposed in the substrate support body, wherein the substrate support body includes an inner portion and a ledge disposed around the inner portion, the ledge positioned above the inner portion. The processing system further includes a controller configured to apply a counter voltage to the electrode in the substrate support body to reduce a sag of a substrate positioned on the ledge of the substrate support body, wherein a portion of the sag of the substrate is caused by a voltage of the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, and the disclosure may admit to other equally effective embodiments.

FIG. 1 shows a processing system, according to one embodiment.

FIG. 2 is a cross-sectional view of the substrate support body from FIG. 1, according to one embodiment.

FIG. 3 is a cross-sectional view of an alternative substrate support body that can be used as part of the substrate support assembly from FIG. 1, according to one embodiment.

FIG. 4 is a cross-sectional view of an alternative substrate support body that can be used as part of the substrate support assembly from FIG. 1, according to one embodiment.

FIG. 5 is a process flow diagram of a method for processing a substrate on the substrate support body of the substrate support assembly of FIGS. 1 and 2, according to one embodiment.

FIG. 6 is a cross-sectional view of an alternative substrate support body that can be used as part of the substrate support assembly from FIG. 1, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to improved substrate supports and related processing systems to be used for processing substrates, such as semiconductor substrates. More particularly, the improved substrate supports can be used in processing systems to limit or prevent damage to the back side of the substrate when the substrate is supported by the substrate support.

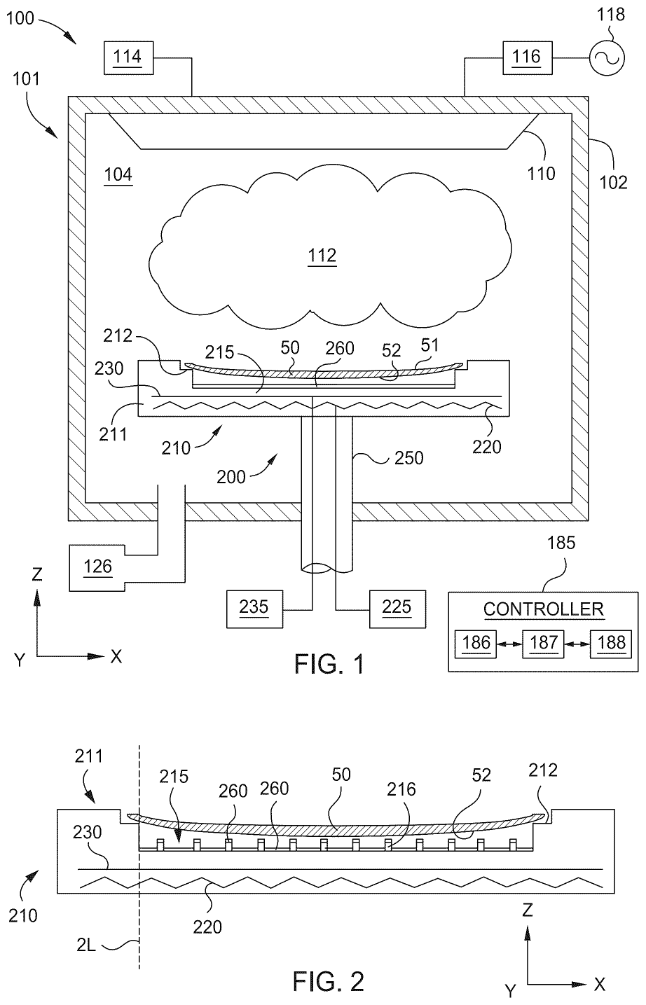

FIG. 1 shows a processing system 100, according to one embodiment. The processing system 100 includes a process chamber 101, a gas supply system 114, an energy source 118, a vacuum pump 126, and a controller 185. The process chamber 101 includes a chamber body 102 enclosing an interior volume 104. In one embodiment, the process chamber 101 is a deposition chamber. In other embodiments, the process chamber 101 can be configured to perform other processes, such as an etching process.

The process chamber 101 can include a showerhead 110 for directing process or cleaning gases into the interior volume 104 of the process chamber 101. The vacuum pump 126 can be used to exhaust gases from the interior volume 104 and to maintain a specified pressure in the interior volume 104 during processing.

In some embodiments, which can be combined with other embodiments, the energy source 118 is a radio frequency (RF) power source. In some of these embodiments, the processing system 100 is configured to generate a plasma 112 of the process or cleaning gases in the interior volume 104 of the process chamber 101 by supplying RF power from the energy source 118 to the showerhead 110. The energy source 118 can be electrically coupled to the showerhead 110 through a matching circuit 116.

The process chamber 101 further includes a substrate support assembly 200 having a substrate support body 210 positioned in the interior volume 104. The substrate support assembly 200 further includes a shaft 250 coupled to the substrate support body 210. In some embodiments, the shaft 250 can be coupled to an actuator (not shown), which can rotate the shaft 250 during processing. A substrate 50 can be positioned on the substrate support body 210. The substrate 50 is shown with an exaggerated sag in the Z-direction. The substrate 50 can include a front side 51 and a back side 52. The rotation of the shaft 250 can be used to rotate the substrate support body 210 and the substrate 50 positioned on the substrate support body 210 during processing. The rotation of the substrate 50 can improve process uniformity for the process (e.g., deposition) being performed on the substrate 50.

The substrate support body 210 can include an outer rim 211 disposed around an inner portion 215. The outer rim 211 can include a ledge 212 extending inwardly towards the inner portion 215. The ledge 212 can also be more generally referred to as a substrate supporting structure. The substrate 50 can be positioned on the ledge 212 during processing. The inner portion 215 is positioned below the ledge 212. Positioning the inner portion 215 below the ledge 212 allows the back side 52 of the substrate 50 to remain above the inner portion 215, so that most of the back side 52 of the substrate 50 does not contact the substrate support body 210. In some embodiments, which can be combined with other embodiments, the inner portion 215 can be positioned at a depth from the ledge 212 that is sufficient to prevent the back side 52 of the substrate 50 from contacting the inner portion 215 even when the substrate 50 sags in the vertical Z-direction. In some embodiments, the inner portion 215 is positioned at a depth from the ledge 212 that is from about 100 micron to about 300 micron, such as about 200 micron.

In some embodiments, which can be combined with other embodiments, the substrate support body 210 can be formed of materials that are electrically insulating while also being thermally conductive, such as aluminum oxide or aluminum nitride. In some embodiments, a coating 260 is formed over a portion (e.g., a central portion) or all of the inner portion 215. For example, in one embodiment, the coating 260 is only formed over a central portion of the inner portion 215 having a diameter from about 4 cm to about 10 cm, such as about 6 cm. This central portion can be the portion of the inner portion 215 that a sagging substrate is most likely to contact.

In some embodiments, which can be combined with other embodiments, the coating 260 can also be formed over the ledge 212 or all of the outer rim 211. The coating 260 is formed of a material suited for a plasma environment, such as a dielectric material (e.g., yttrium oxide (Y₂O₃)), that is softer than the material(s) used to form the substrate 50 (e.g., silicon) and the substrate support body 210 (e.g., aluminum nitride). The softer material of the coating 260 can reduce or prevent damage to the back side 52 of the substrate 50 if the back side 52 of the substrate 50 does contact portions of the substrate support body 210, such as the ledge 212 or inner portion 215. The coating 260 can also be formed over the dimples 216 described below in reference to FIG. 2.

The substrate support assembly 200 can further include a heater 220 (e.g., a resistive heater) positioned inside the substrate support body 210. The heater 220 can be connected to an electrical power source 225. The heater 220 can be configured to heat the substrate 50 during processes, such as depositions, when electrical power is provided to the heater 220 from the electrical power source 225.

The plasma 112 generated in the interior volume 104 often increases the forces on the substrate 50 in the downward Z-direction to levels greater than would be present from gravitational forces alone. These increased forces are electrostatic forces, for example the type of force used by electrostatic chucks to retain substrates on substrate supports. These increased forces are due to a bias voltage (also referred to as substrate voltage) that is developed on the substrate 50 when the plasma 112 is generated, which results in an attractive force between the substrate 50 and the substrate support body 210. This increased force can cause damage on portions of the back side 52 of the substrate 50 contacting the substrate support body 210. This increased force can also cause additional portions of the back side 52 of the substrate 50 to contact the substrate support body 210, such as contacting the dimples 216 described below in reference to FIG. 2. This additional contact can lead to damage on portions of the back side 52 of the substrate, which were not intended to contact the substrate support body 210.

The substrate support assembly 200 can further include an electrode 230 positioned inside the substrate support body 210. The electrode 230 can be connected to an electrical power source 235. The electrode 230 can be configured to provide a counter voltage to the electrode 230 to offset the additional downward forces in the Z-direction on the substrate 50 resulting from the bias voltage on the substrate 50 caused by the plasma 112.

The counter voltage applied from the electrical power source 235 to the electrode 230 can be used to counteract the bias voltage on the substrate 50 caused by the plasma 112, which results in less force on the portions of the back side 52 of the substrate 50 that contact the substrate support body 210. The counter voltage applied from the electrical power source 235 to the electrode 230 can also result in less contact between the back side 52 of the substrate 50 and the substrate support body 210, such as contact of the back side 52 of the substrate 50 with the dimples 216 described below in reference to FIG. 2.

The voltage applied to the electrode 230 can also be used to cause the back side 52 of the substrate 50 to have a more uniform distance from the inner portion 215 across the substrate 50 from center to edge. For example, the bias voltage on the substrate 50 resulting from the plasma can cause the substrate 50 to sag more in the downward Z-direction than the substrate 50 would sag from gravity alone. Thus, the counter voltage applied to the electrode 230 can reduce this additional sag of the substrate 50 caused by the bias voltage, which reduces the variability of the distance between the back side 52 of the substrate 50 and the inner portion 215 across the inner portion 215. This reduction in the variability of the distance between the back side 52 of the substrate 50 and the inner portion 215 improves the uniformity of the heat transfer from the substrate support body 210 to the substrate 50 across the substrate 50 from center to edge, which improves the uniformity of the temperature across the substrate 50 during processes, such as plasma depositions. The improvement of temperature uniformity improves the uniformity of the process being performed, such as an improvement in deposition thickness across the substrate 50 from the center of the substrate 50 to the edge of the substrate 50.

Furthermore, in some embodiments, which can be combined with other embodiments, the bias voltage of the substrate 50 vary during a process, such as a plasma deposition. This variation in the bias voltage can cause the downward sag of the substrate 50 in the Z-direction to vary during the process when a counter voltage is not applied to the electrode 230. For example, the bias voltage can gradually increase to a steady state bias voltage after the plasma is initiated in the interior volume 104. To address the time-varying sag of the substrate 50, the counter voltage applied to the electrode 230 can be configured to follow a similar time-varying profile. For example, if the bias voltage on the substrate 50 is configured to increase from a value of OV before the plasma is initiated to a substantially steady state value of +50V 60 seconds after the plasma is initiated, then the counter voltage applied to the electrode 230 can be configured to follow a similar voltage profile with the same polarity. For example, if the bias voltage on the substrate 50 from the plasma process ramps from OV to +50V over 60 seconds, then a counter voltage applied to the electrode 230 can be configured ramp in a substantially mirror image from OV to +50V over the same 60 seconds.

The processing system 100 also includes the controller 185 for controlling processes performed by the processing system 100. The controller 185 can be any type of controller used in an industrial setting, such as a programmable logic controller (PLC). The controller 185 includes a processor 187, a memory 186, and input/output (I/O) circuits 188. The controller 185 can further include one or more of the following components (not shown), such as one or more power supplies, clocks, communication components (e.g., network interface card), and user interfaces typically found in controllers for semiconductor equipment.

The memory 186 can include non-transitory memory. The non-transitory memory can be used to store the programs and settings described below. The memory 186 can include one or more readily available types of memory, such as read only memory (ROM) (e.g., electrically erasable programmable read-only memory (EEPROM), flash memory, floppy disk, hard disk, or random access memory (RAM) (e.g., non-volatile random access memory (NVRAM).

The processor 187 is configured to execute various programs stored in the memory 186, such as deposition processes, etching processes, cleaning processes, etc. During execution of these programs, the controller 185 can communicate to I/O devices through the I/O circuits 188. For example, during execution of these programs and communication through the I/O circuits 188, the controller 185 can control outputs, such as energizing the energy source 118, adjusting the voltage applied to the electrode 230, or changing the position of valves (not shown) to send process gases to the interior volume 104 of the process chamber 101. The memory 186 can further include various operational settings used to control the processing system 100. For example, the settings can include durations for how long the different valves remain open or closed during different depositions or other processes.

FIG. 2 is a cross-sectional view of the substrate support body 210 from FIG. 1, according to one embodiment. The view in FIG. 2 shows additional detail of the substrate support body 210. An imaginary line 2L shows the location where the outer rim 211 connects with the inner portion 215.

The substrate support body 210 can additionally include a plurality of dimples 216 extending upward from the inner portion 215. The dimples 216 were not shown in FIG. 1 in order to avoid cluttering the drawing. In some embodiments, the dimples 216 can have a height in the Z-direction from about 10 micron to about 50 micron, such as about 30 micron. The dimples 216 are shown below the ledge 212 in FIG. 2, but in some embodiments, the top of the dimples 216 can be positioned at the same height as the ledge 212 to prevent the center of the substrate 50 from sagging below the outer edges of the substrate 50.

The dimples 216 are configured to support sagging portions of the substrate 50 while having a small surface area in the XY plane, so that only a small surface area of the back side 52 of the substrate 50 contacts the dimples 216 when there is contact between the substrate 50 and the dimples 216. The dimples 216 are only one example of supporting structures that can be used to support the back side 52 of the substrate 50 and numerous other structures can be used, such as bumps, ridges, etc. In the event there is contact between the back side 52 of the substrate 50 and the dimples 216, then damage to the back side 52 of the substrate 50 often occurs. Chemical mechanical planarization/polishing (CMP) of the back side 52 of the substrate 50 is often used to remove these damaged portions. Avoiding contact between the back side 52 of the substrate 50 and the dimples 216 or other portions of the inner portion 215 can reduce the costs of forming products with the substrate 50 when costly operations, such as CMP can be avoided.

In some embodiments, which can be combined with other embodiments, the dimples 216 can be polished to reduce the amount of damage to the back side 52 of the substrate 50 in the event there is contact between the back side 52 of the substrate and the dimples 216. For example, in one embodiment dimples 216 having a roughness average (Ra) of Ra 30 μin can be polished to a roughness from about Ra 2 μin to about Ra 6 μin, such as about Ra 4 μin. Furthermore, in some embodiments, the dimples 216 can be omitted to provide additional space in the Z-direction between the back side 52 of the substrate 50 and the inner portion 215. For embodiments in which the dimples 216 are omitted, the inner portion 215 can be polished to have a similar roughness average as those values described above for the dimples 216 (e.g., Ra 4 μin).

In some embodiments, which can be combined with other embodiments, the coating 260 formed of relatively soft material (e.g., yttrium oxide) can also be formed over the dimples 216. The coating 260 formed over the inner portion 215 and the dimples 216 can have a thickness from about 0.1 micron to about 10 micron, such as from about 0.2 micron to about 1.0 micron, such as about 0.5 micron.

As discussed above, the bias voltage that develops on the substrate 50 during plasma processing can result in the substrate 50 being forced towards the substrate support body 210 with higher levels of force. These higher levels of force can result in unintended contact between the back side 52 of the substrate 50 and the dimples 216. This unintended contact can damage the substrate 50. To prevent this unintended contact, the counter voltage of substantially the same magnitude (e.g., within 5%) and same polarity can be applied to the electrode 230 to offset the attractive forces between the substrate 50 and substrate support body 210 caused by the bias voltage on the substrate 50 that is caused by the plasma process. For example, if a bias voltage developed on the substrate 50 for a given plasma process is determined to be +50V, then a counter voltage of +50V can be applied to the electrode 230 to offset the bias voltage on the substrate 50.

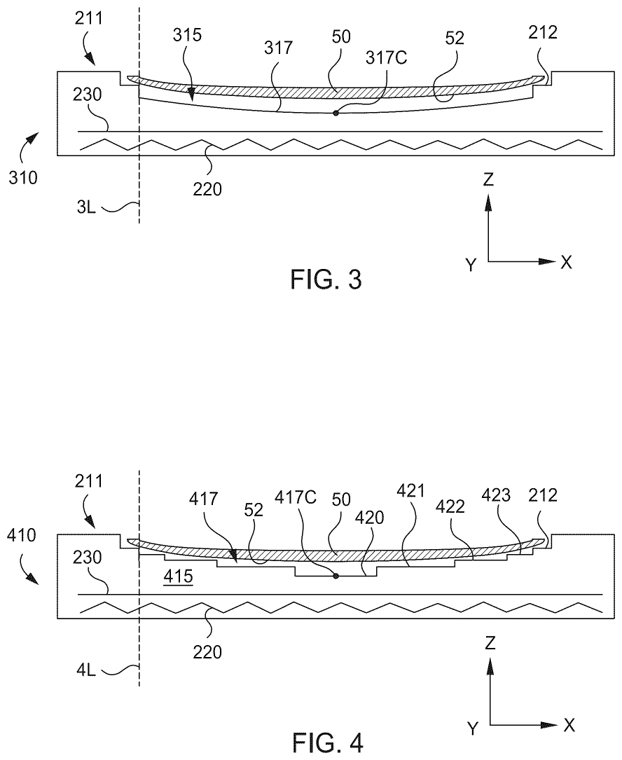

FIG. 3 is a cross-sectional view of an alternative substrate support body 310 that can be used as part of the substrate support assembly 200 from FIG. 1, according to one embodiment. The substrate support body 310 is the same as the substrate support body 210 described above except that the substrate support body 310 includes an inner portion 315 that is different than the inner portion 215 of the substrate support body 210. An imaginary line 3L shows the location where the outer rim 211 connects with the inner portion 315. Although not shown, in some embodiments, the substrate support body 310 can further include the coating 260 and the dimples 216 described above in reference to the substrate support body 210.

The inner portion 315 includes a top surface 317 that is curved. The curve of the top surface 317 can have a concave profile. In some embodiments, a center 317C of the top surface 317 is located at a lowest position in the Z-direction for the whole top surface 317. The curve of the top surface 317 can be configured to closely follow the sag of the substrate 50, which enables the distance between the back side 52 of the substrate 50 and the top surface to remain relatively constant across the substrate 50. Having the top surface 317 formed to follow the sag of the substrate 50 enables the distance between the back side 52 of the substrate 50 and the top surface 317 of the inner portion 315 to remain relatively constant across the inner portion 315. Keeping the distance between the back side 52 the substrate and the top surface 317 of the inner portion 315 relatively constant across the inner portion 315 also allows the electrode 230 to use the counter voltage to apply a force with that is substantially uniform across the inner portion 315. This substantially uniform force can offset the attractive force between the substrate 50 and the substrate support body 310 caused by the bias voltage resulting from the plasma process.

When (1) the uniformity of the distance between the back side 52 of the substrate 50 and the top surface 317 of the inner portion 315 is improved and (2) the uniformity of the force applied to the substrate 50 from the counter voltage of the electrode 230 is also improved across the substrate 50, then the likelihood of contact between back side 52 of the substrate 50 and inner portion 315 is reduced. This reduction of contact between the back side 52 of the substrate 50 and the inner portion 315 results in less damage to the substrates 50 being processed, which eventually leads to improved performance of the devices formed on the substrate 50. This reduction of contact can also reduce manufacturing costs as additional operations like CMP of the back side of the substrate can be avoided or there can be a reduction in the amount of polishing used on the back side of the substrate in a CPM process (e.g., a reduction of 1.0 micron of polishing to 0.3 micron of polishing) due to the lower amounts of force on the back side of the substrate when there is contact between the back side of the substrate and the substrate support body.

FIG. 4 is a cross-sectional view of an alternative substrate support body 410 that can be used as part of the substrate support assembly 200 from FIG. 1, according to one embodiment. The substrate support body 410 is the same as the substrate support body 210 described above except that the substrate support body 410 includes an inner portion 415 that is different than the inner portion 215 of the substrate support body 210. An imaginary line 4L shows the location where the outer rim 211 connects with the inner portion 415. Although not shown, in some embodiments, the substrate support body 410 can further include the coating 260 and the dimples 216 described above in reference to the substrate support body 210.

The inner portion 415 includes a top surface 417 that includes a central portion 420 and a plurality of steps 421-423 positioned around the central portion 420. The central portion 420 is positioned lower in the Z-direction than the steps 421-423. In some embodiments, the central portion 420 has a circular shape when viewed from above. Each step 421-423 can have a ring shape when viewed from above. The first step 421 can be positioned around the central portion 420 at a location in the Z-direction that is higher than the central portion 420. The second step 422 can be positioned around the first step 421 at a location in the Z-direction that is higher than the first step 421. The third step 423 can be positioned around the second step 422 at a location in the Z-direction that is higher than the second step 422.

The central portion 420 and the steps 421-423 of the top surface 417 result in there being less variation across the inner portion 415 for the distance between the back side 52 of the substrate 50 and the top surface 417 of the inner portion 415 because the central portion 420 and the steps 421-423 of the top surface 417 more closely follow the sag of the substrate 50 when compared to a substrate support body with an inner portion having a flat surface. Reducing the variation of the distance between the back side 52 of the substrate 50 and the top surface 417 of the inner portion 415 allows for the electrode 230 to apply a more uniform force across the substrate 50 with the counter voltage to offset the forces from the bias voltage of the plasma process that can lead to damage of the substrate 50 when the back side 52 of the substrate 50 contacts the inner portion of the substrate support body.

When (1) the uniformity of the distance between the back side 52 of the substrate 50 and the top surface 417 of the inner portion 415 is improved and (2) the uniformity of the force applied to the substrate 50 from the counter voltage of the electrode 230 is also improved across the substrate 50, then the likelihood of contact between the back side 52 of the substrate 50 and the inner portion 415 is reduced. This reduction in the likelihood of contact between the back side 52 of the substrate 50 and the inner portion 415 results in less damage to the substrate 50, which eventually leads to improved performance of the devices formed on the substrate 50 and reduced manufacturing costs when operations, such as CMP can be avoided or reduced as described above.

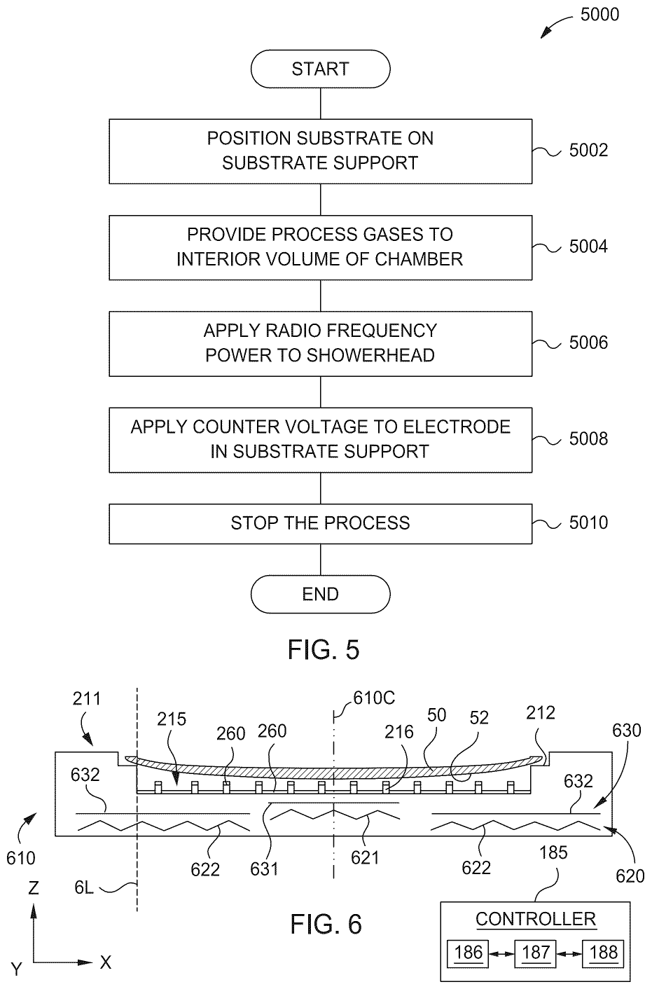

FIG. 5 is a process flow diagram of a method 5000 for processing a substrate on the substrate support body 210 of the substrate support assembly 200 of FIGS. 1 and 2, according to one embodiment. The method 5000 is described in reference to FIGS. 1-4. The controller 185 can execute one or more programs stored in the memory 186 to perform the method 5000. For example, the controller 185 can open one or more valves (not shown) to provide gases to the process chamber 101, provide RF power to the showerhead 110, and apply counter voltage to the electrode 230 among other operations.

The method 5000 begins at block 5002. At block 5002, a substrate 50 is positioned on the ledge 212 of the substrate support body 210. The back side 52 of the substrate 50 remains spaced apart from the inner portion 215 as the ledge 212 supports the substrate 50 above the inner portion 215.

At block 5004, one or more process gases are provided to the interior volume 104 of the process chamber 101 through the showerhead 110. The one or more process gases can be provided from the gas supply system 114 to the interior volume 104.

At block 5006, radio frequency power is provided to the showerhead 110 to generate the plasma 112 in the interior volume 104 of the process chamber 101. The plasma 112 causes a bias voltage to develop on the substrate 50. The radio frequency power can be provided by the energy source 118 to the showerhead 110 through the matching circuit 116. The plasma 112 is used to perform the process (e.g., deposition) on the substrate 50.

At block 5008, the counter voltage is applied to the electrode 230. The counter voltage has the same polarity as the bias voltage that develops on the substrate 50 as a result of the plasma. Furthermore, the counter voltage can have a magnitude that is substantially equal (e.g., within 5%) to the magnitude of the bias voltage on the substrate 50. For example, if the bias voltage is determined to be +50V, then the counter voltage can be applied at +50V.

The counter voltage can be used to offset the additional downward forces from the bias voltage in the Z-direction on the substrate 50 that can result in additional sag of the substrate 50 in the Z-direction (i.e., sag that is in excess of the sag from gravity alone). The counter voltage applied to the electrode 230 can be used to prevent the back side 52 of the substrate 50 from contacting the inner portion 215. The counter voltage applied to the electrode 230 can also help maintain a more uniform distance between the back side 52 of the substrate 50 and the inner portion 215. Maintaining a more uniform distance between the back side 52 the substrate 50 and the inner portion 215 can improve the uniformity of the heat transfer from the inner portion 215 to the substrate 50, which can improve the temperature uniformity of the substrate 50 from the center of the substrate 50 to the edge of the substrate 50 during processes, such as a plasma deposition. This improvement in temperature uniformity of the substrate 50 can improve the uniformity of the process performed on the substrate 50, such as improvements in deposition thickness uniformity across the substrate 50 for a plasma deposition.

The curved top surface 317 of the substrate support body 310 (see FIG. 3) and the stepped top surface 417 of the substrate support body 410 (see FIG. 4) can be used to further improve the uniformity of the distance between the back side 52 of the substrate 50 and the corresponding inner portions 315, 415 of the respective substrate support bodies 310, 410. These further improvements in the distance uniformity lead to further improvements in temperature uniformity across the substrate 50, which in turn leads to further improvements in the uniformity of the process results, such as deposition thickness uniformity on the substrate 50 from the center of the substrate 50 to the edge of the substrate 50.

In some embodiments, which can be combined with other embodiments, the counter voltage applied to the electrode 230 can be varied over time to follow variations in the bias voltage over the same time period. For example, if the bias voltage on the substrate 50 ramps up from a starting voltage of OV to a maximum value of +50V after a time period of 60 seconds starting when the plasma 112 is initiated in the interior volume 104 of the process chamber 101, then the counter voltage applied to the electrode 230 can be configured to ramp up from a starting voltage of 0 volts to a maximum voltage of +50V over the same time period. Furthermore, the counter voltage applied to the electrode 230 can be configured to follow a profile that is similar to the changes in the bias voltage on the substrate 50 as the counter voltage increases to its maximum value. For example, if the bias voltage ramps up from zero volts to +50V along a linear profile, then counter voltage applied to the electrode can configured to ramp up from zero volts to +50V along a corresponding linear profile with the same slope. Similarly, if the bias voltage on the substrate 50 ramps up from zero volts to +50V along a nonlinear profile, then the counter voltage applied to the electrode 2:30 can be ramped up from zero volts to +50V along a closely fitting nonlinear profile. Having the counter voltage applied to the electrode 230 follow the changes in the bias voltage on the substrate 50 during a process (e.g., a plasma deposition) can lead to further improvements in the uniformity of the distance between the back side 52 of the substrate 50 and the inner portion of the substrate support body during the process. This improvement in distance uniformity through the duration of the process being performed leads to improvements in temperature uniformity of the substrate 50 from the center to the edge of the substrate 50 through the duration of the process being performed, which in turn leads to improvements in the uniformity of the process results, such as deposition thickness uniformity from the center to the edge of the substrate 50.

At block 5010, the process is stopped. The process gases from the gas supply system 114 are no longer provided to the interior volume 104 of the process chamber. The RF power from the energy source 118 is no longer provided to the showerhead 110. The counter voltage applied to the electrode 230 is stopped.

FIG. 6 is a cross-sectional view of an alternative substrate support body 610 that can be used as part of the substrate support assembly 200 from FIG. 1, according to one embodiment. An imaginary line 6L shows the location where the outer rim 211 connects with the inner portion 215 of the substrate support body 610. The substrate support body 610 is the same as the substrate support body 210 described above (see FIGS. 1 and 2) except that the substrate support body 610 includes a heater 620 and an electrode arrangement 630, which are different than the heater 220 and the electrode 230 described above in reference to the substrate support body 210. For example, the heater 620 in the substrate support body 610 includes a first heating element 621 and a second heating element 622 instead of the single heater 220 with a single heating element included in the substrate support body 210. Similarly, the electrode arrangement 630 in the substrate support body 610 includes a first electrode 631 and a second electrode 632 instead of the single electrode 230 included in the substrate support body 210.

The second heating element 622 can be positioned around the first heating element 621. The second heating element 622 can have the shape of a ring when viewed from above. In some embodiments as shown, the first heating element 621 has a structure that extends across the center through a central vertical axis 610C of the substrate support body 610. In other embodiments, the first heating element 621 can have a structure (e.g., a ring or spiral structure) that extends around the central vertical axis 610C of the substrate support body 610. The heating elements 621, 622 are configured to be operated independently, so that the heat provided by the first heating element 621 is independent from the heat provided by the second heating element 622. For example, in one embodiment, the heating elements 621, 622 are connected to separate electrical circuits that are individually controlled by the controller 185, so that the controller 185 can adjust the heat provided by each heating element 621, 622. Furthermore, in some embodiments as shown in FIG. 6, the heating elements 621. 622 can be positioned at different vertical locations in the Z-direction. Positioning the heating elements at different vertical locations can assist in obtaining a more uniform substrate temperature during processing.

Although two heating elements 621, 622 are shown, other embodiments can include three or more heating elements. For example, one embodiment can include five individually controlled heating elements that include a central heating element surrounded by four outer heating elements with each outer heating element located at a different radial distance from the central vertical axis of the substrate support body.

The second electrode 632 can be positioned around the first electrode 631. The second electrode 632 can have the shape of a ring when viewed from above. In some embodiments as shown, the first electrode 631 has a structure that extends across the center through the central vertical axis 610C of the substrate support body 610. In other embodiments, the first electrode 631 can have a structure (e.g., a ring or spiral structure) that extends around the central vertical axis 610C of the substrate support body 610. The electrodes 631, 632 are configured to be operated independently, so that the counter voltage provided to the first electrode 631 is independent from the counter voltage provided to the second electrode 632. For example, in one embodiment, the electrodes 631, 632 are connected to separate electrical circuits that are individually controlled by the controller 185, so that the controller 185 can apply a first counter voltage to the first electrode 631 and a second counter voltage to the second electrode 632. Applying separate voltages to the electrodes 631, 632 can be useful when the bias voltage varies across the substrate 50 (e.g., from center to edge) during the process and/or when the distance between the corresponding electrodes 631, 632 and the substrate 50 vary across the substrate 50 (e.g., from center to edge).

Furthermore, in some embodiments as shown in FIG. 6, the electrodes 631. 632 can be positioned at different vertical locations in the Z-direction. Positioning the electrodes at different vertical locations can be used assist in obtaining a more uniform distance between the back side 52 of the substrate 50 and the substrate support body 610 across the inner portion 215, which can assist in obtaining a more uniform temperature across the substrate from center to edge during processing.

Although two electrodes 631, 632 are shown, other embodiments can include three or more electrodes. For example, one embodiment can include five individually controlled electrodes that include a central electrode surrounded by four outer electrodes with each outer electrode located at a different radial distance from the central vertical axis of the substrate support body.

What is claimed is:

1. A processing system for processing a substrate comprising:
a process chamber comprising:
a chamber body disposed around an interior volume;
a substrate support assembly positioned in the interior volume, the substrate support assembly comprising a substrate support body and a first electrode disposed in the substrate support body, wherein
the substrate support body includes an inner portion and a ledge disposed around the inner portion, the ledge positioned above the inner portion; and
a controller configured to perform a process on a substrate that is positioned on the substrate support body in the interior volume of the process chamber; and
apply a first counter voltage to the first electrode in the substrate support body based on a substrate voltage of the substrate during the process performed on the substrate in the interior volume of the process chamber.

2. The processing system of claim 1, wherein
the first counter voltage has a same polarity as the substrate voltage, and
a magnitude of the first counter voltage is substantially equal to a magnitude of the substrate voltage.

3. The processing system of claim 2, further comprising a second electrode disposed in the substrate support body, wherein
the second electrode is positioned around the first electrode, and
the controller is further configured to apply a second counter voltage to the second electrode during the process performed on the substrate in the interior volume of the process chamber.

4. The processing system of claim 3, wherein the first electrode is positioned at first vertical location in the substrate support body and the second electrode is positioned at a second vertical location in the substrate support body.

5. The processing system of claim 1, wherein a top surface of the inner portion of the substrate support body is a curved surface with a concave profile.

6. The processing system of claim 5, wherein the concave profile of the top surface of the inner portion substantially matches the curve of the substrate positioned on the substrate support body.

7. The processing system of claim 1, wherein a top surface of the inner portion of the substrate support body includes a central portion and a plurality of steps positioned around the central portion, the central portion positioned below the plurality of steps.

8. The processing system of claim 7, wherein the plurality of steps includes a first step disposed around the central portion and a second step disposed around the first step, wherein the first step is positioned above the central portion and the second step is positioned above the first step.

9. The processing system of claim 1, wherein a coating is formed over a top surface of the inner portion of the substrate support body, the coating formed of a softer material than the substrate support body.

10. The processing system of claim 1, wherein the substrate support body includes a plurality of dimples extending upward from the inner portion, wherein a coating is formed over each dimple, the coating formed of a softer material than the dimples.

11. A method of processing a substrate comprising:
positioning a substrate on a substrate support body of a substrate support assembly in an interior volume of a process chamber, wherein the substrate support assembly includes an electrode disposed in the substrate support body;
providing one or more gases to the interior volume of the process chamber through a showerhead positioned over the substrate support body;
applying radio frequency energy to the showerhead to generate a plasma in the interior volume of the process chamber,
performing a process on the substrate positioned on the substrate support body with the generated plasma;
determining a magnitude of a substrate voltage developed on the substrate during the process performed on the substrate; and
applying a counter voltage to the electrode in the substrate support body based on the substrate voltage of the substrate during the process performed on the substrate, wherein a magnitude of the counter voltage applied to the electrode is based on the magnitude of the substrate voltage.

12. The method of claim 11, wherein the substrate voltage and the counter voltage have a same polarity.

13. The method of claim 12, wherein a magnitude of the counter voltage is substantially equal to a magnitude of the substrate voltage.

14. The method of claim 11, wherein a top surface of an inner portion of the substrate support body is a curved surface with a concave profile.

15. The method of claim 14, wherein the concave profile of the top surface of the inner portion substantially matches the curve of the substrate positioned on the substrate support body.

16. The method of claim 11, wherein a top surface of an inner portion of the substrate support body includes a central portion and a plurality of steps positioned around the central portion, the central portion positioned below the plurality of steps.

17. The method of claim 16, wherein
the plurality of steps includes a first step disposed around the central portion and a second step disposed around the first step, and
the first step is positioned above the central portion and the second step is positioned above the first step.

18. The method of claim 11, wherein the counter voltage is varied during a first time period when the process is performed on the substrate based on variations of the substrate voltage during the first time period.

19. A processing system for processing a substrate comprising:
a process chamber comprising:
a chamber body disposed around an interior volume;
a substrate support assembly positioned in the interior volume, the substrate support assembly comprising a substrate support body and an electrode disposed in the substrate support body, wherein
the substrate support body includes an inner portion and a ledge disposed around the inner portion, the ledge positioned above the inner portion; and
a controller configured to apply a counter voltage to the electrode in the substrate support body to reduce a sag of a substrate positioned on the ledge of the substrate support body, wherein a portion of the sag of the substrate is caused by a voltage of the substrate.

20. The processing system of claim 19, wherein the controller is further configured to modify the counter voltage during a first time period when a process is performed on the substrate based on variations of the substrate voltage during the first time period.
